(19) United States
(12) Patent Application Publication
(10) Pub. No.: US 2015/0255493 A1
(43) Pub. Date: Sep. 10, 2015

(54) DISPLAY DEVICE AND METHOD OF MANUFACTURING THE SAME

(71) Applicant: Samsung Display Co., Ltd., Yongin-City (KR)

(72) Inventors: Seung-Bo SHIM, Asan-si (KR); Bong-Yeon KIM, Seoul (KR); Jun-hyuk WOO, Yongin-si (KR); Jeong-Won KIM, Seoul (KR); Kwang-Woo PARK, Hwaseong-si (KR)

(21) Appl. No.: 14/604,480

(22) Filed: Jan. 23, 2015

(30) Foreign Application Priority Data
Mar. 5, 2014 (KR) 10-2014-0025870

(51) Int. Cl. H01L 27/12; G03F 1/26

(52) U.S. Cl. CPC H01L 27/1288; H01L 27/1222; H01L 27/124; G03F 1/26

(57) ABSTRACT

A display device includes a substrate comprising a display area and a non-display area. A gate line and a data line are disposed on the substrate. A thin film transistor is disposed on the display area and coupled to the gate line and the data line. A pad is disposed in the non-display area. A passivation layer is disposed on the thin film transistor and the pad. A pixel electrode is coupled to the thin film transistor. The passivation layer has a thickness that is smaller in the non-display area than in the display area, and the passivation layer has a thickness of about 0.1 μm to about 1 μm in the non-display area.

### CROSS-REFERENCE TO RELATED APPLICATION

This application claims priority to and the benefit of Korean Patent Application No. 10-2014-0025870, filed on Mar. 5, 2014, with the Korean Intellectual Property Office, the disclosure of which application is incorporated herein in its entirety by reference.

### BACKGROUND

1. Field

Embodiments relate to a display device in which contact openings (e.g., holes) of a display area and a non-display area are simultaneously formed by using an exposure mask differently forming contact opening-forming mask patterns that are intended to be disposed in the display area and the non-display area, and to a manufacturing method of the display device.

2. Description of Related Technology

In general, flat or otherwise thin panel displays (FPDs) such as liquid crystal displays and organic light emitting diode displays include opposed electric field generating electrodes and an electro-optically active layer disposed to be affected by correspondingly generated electric fields. In the case of the liquid crystal display, a liquid crystal layer is included as the electro-optically active layer, and in the case of the organic light emitting diode display, an organic light emitting layer is included as the electro-optically active layer.

One of the opposed electric field generating electrodes is generally connected to a switching element so that it receives an electrical signal on a selective basis. The electro-optically active layer is affected by the received electrical signal such that it forms a corresponding optical signal as part of a formed and to be displayed image.

According to one trend in the mass production of large area and highly integrated display devices, phase shift masks are used to form fine lithographic patterns. An aspect of phase shift masks is that they can be structured to allow graded amounts (e.g., small amounts) of light as well as bright light to be transmitted therethrough as compared to binary masks which are either all on or all off in terms of transmitted through light rays. On the other hand, to produce a finely patterned area, e.g., through positive development of photoreactive layers, it is often required to be intensively exposed to light when using the phase shift masks. However, the phase shift masks decrease the amounts of light to be transmitted therethrough, and thus increase the amount of light radiated by an exposure apparatus so as to form a fine pattern.

Meanwhile, with respect to a configuration in which a passivation layer is formed on a gate line, a gate insulating layer, a semiconductor, a data line, and the like on a display substrate of a thin film transistor, if the passivation layer is too high in a pad portion of a non-display area, a conductive ball is used. The conductive ball brings an external circuit such as a driver chip into contact with a pad, pushes up the external circuit, thereby increasing contact resistance between the external circuit and the pad, so that signals are not transmitted.

Therefore, in the case where a contact opening is formed in a passivation layer to expose a pad portion of a non-display area, the passivation layer in which the contact opening is formed and in another portion of the non-display area is exposed to light, so that a height of the passivation layer is lowered.

However, in the case where contact openings that are to be formed in a display area and in a non-display area are simultaneously formed using a phase shift mask and the total amount of light transmitted through the phase shift mask is increased, because a passivation layer of the non-display area is excessively etched, conductive lines disposed on a lower portion of the passivation layer may be undesirably exposed.

It is to be understood that this background of the technology section is intended to provide useful background for understanding the here disclosed technology and as such, the technology background section may include ideas, concepts or recognitions that were not part of what was known or appreciated by those skilled in the pertinent art prior to corresponding effective filing dates of subject matter disclosed herein.

### SUMMARY

Aspects of embodiments are directed to a display device and to a mass production method of manufacturing the same. Additional aspects of embodiments are directed to a display device manufactured by using an exposure mask that differently forms contact opening-forming mask patterns of a display area and a non-display area utilizing a phase shift material.

According to an embodiment, a display device includes a substrate including a display area and a non-display area. A gate line and a data line are disposed on the substrate. A thin film transistor is disposed on the display area and coupled to the gate line and the data line. A pad is disposed in the non-display area. A passivation layer is disposed on the thin film transistor and the pad. A pixel electrode is coupled to the thin film transistor. The passivation layer has a thickness that is smaller in the non-display area than in the display area, and the passivation layer has a thickness of about 0.1 μm to about 1 μm in the non-display area.

The passivation layer may have an opening that extends to a drain electrode of the thin film transistor and the pad.

According to an embodiment, an exposure mask includes a mask substrate including a first area and a second area. A first mask pattern is disposed in the first area, the first mask pattern having a first light transmitting unit. A second mask pattern is disposed in the second area, the second mask pattern having a second light transmitting unit and a second phase shift unit.

The first mask pattern may include a first phase shift unit surrounding the first light transmitting unit.

The first light transmitting unit may have a circular or polygonal shape.

The first phase shift unit may have a light transmittance of about 1% to about 10%.

The second phase shift unit may include a plurality of phase shift patterns spaced apart and parallel to each other, and a light transmission area between the phase shift patterns.

The phase shift pattern may have a linewidth of about 0.5 μm to about 1.2 μm and the light transmission area may have a linewidth of about 0.8 μm to about 1.5 μm.

The phase shift pattern and the light transmission area may have a shape of a stripe.

The second phase shift unit may include a plurality of phase shift patterns spaced apart and parallel to each other, light blocking patterns placed substantially parallel to each other between the phase shift patterns, and a light transmission area between the phase shift pattern and the light blocking pattern.

The phase shift pattern, the light blocking pattern, and the light transmission area may have a shape of a stripe.

The second phase shift unit may include at least one phase shift pattern spaced apart and parallel to each other, at least one light blocking pattern adjacent to the phase shift pattern, and a light transmission area between the phase shift pattern and the light blocking pattern that are adjacent to each other.

The phase shift pattern, the light blocking pattern, and the light transmission area may have a shape of a stripe.

According to an embodiment, a method for manufacturing a display device includes the following. A passivation layer-forming material is applied on a substrate including a display area and a non-display area. The passivation layer-forming material applied to the display area and the non-display area is exposed to light using different patterns on an exposure mask. A contact opening is formed by developing the light-exposed passivation layer-forming material. A passivation layer is formed by applying a heat treatment to the residual passivation layer-forming material.

The exposure mask may include a mask substrate including a first area and a second area. The first mask pattern is disposed in the first area, the first mask pattern having a first light transmitting unit. A second mask pattern is disposed in the second area, the second mask pattern having a second light transmitting unit and a second phase shift unit.

The first mask pattern may include a first phase shift unit surrounding the first light transmitting unit.

The second phase shift unit may include a plurality of phase shift patterns spaced apart and parallel to each other, and a light transmission area between the phase shift patterns.

The second phase shift unit may include a plurality of phase shift patterns spaced apart and parallel to each other, light blocking patterns placed substantially parallel to each other between the phase shift patterns, and a light transmission area between the phase shift pattern and the light blocking pattern.

The second phase shift unit may include at least one phase shift pattern spaced apart and parallel to each other, at least one light blocking pattern adjacent to the phase shift pattern, and a light transmission area between the phase shift pattern and the light blocking pattern that are adjacent to each other.

According to embodiments, a display device is capable of realizing a fine contact hole of a display area, reducing the amount of light incident on a non-display area, adjusting a height of a passivation layer disposed in the non-display area, and lowering a height of an uneven pattern formed on the passivation layer disposed in the non-display area.

The foregoing is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

The above and other features and aspects of the inventive concept will be more clearly understood from the following detailed description taken in conjunction with the accompanying drawings, in which:

FIG. 1 is a schematic plan view showing a display device according to a first embodiment;

FIG. 2 provides comparative cross-sectional views for comparing intensity of light transmitted through different kinds of masks, more specifically, phase shift masks and binary masks;

FIG. 3 is cross-sectional views showing an uneven pattern formed on a passivation layer disposed in a non-display area;

FIGS. 4A and 4B are a plan view and a cross-sectional view, respectively showing a first mask pattern and a second mask pattern according to the first embodiment;

FIGS. 5A and 5B are a plan view and a cross-sectional view, respectively showing a second mask pattern according to a second embodiment;

FIGS. 6A and 6B are a plan view and a cross-sectional view, respectively showing a second mask pattern according to a third embodiment;

FIGS. 7A, 7B, 7C, and 7D are graphs showing the amounts of light incident on a passivation layer of a non-display area according to some embodiments;

FIG. 8 is cross-sectional views of the display device illustrated in FIG. 1; and

FIGS. 9A, 9B, and 9C are cross-sectional views showing a method of forming a contact hole of a display device using an exposure mask according to the first embodiment.

### DETAILED DESCRIPTION

Features of structures formed in accordance with the present disclosure and methods for achieving them will be made clear from embodiments described below in more detail with reference to the accompanying drawings. The present teachings may, however, be embodied in many different forms and should not be construed as being limited to the specific embodiments set forth herein. Rather, these embodiments are provided so that this disclosure will be thorough and complete, and will fully convey the scope of the present teachings to those skilled in the pertinent art. Like reference numerals refer to like elements throughout the specification.

The spatially relative terms “below”, “beneath”, “lower”, “above”, “upper”, and the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device shown in the drawing is turned over, the device positioned “below” or “beneath” another device may be placed “above” another device. Accordingly, the illustrative term “below” may include both the lower and upper positions. The device may also be oriented in the other direction, and thus the spatially relative terms may be interpreted differently depending on the orientations.

The terminology used herein is for the purpose of describing particular embodiments only and is not construed as limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of mentioned component, step, operation and/or element, but do not exclude the presence or addition of one or more other components, steps, operations and/or elements.

Unless otherwise defined, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the present specification.

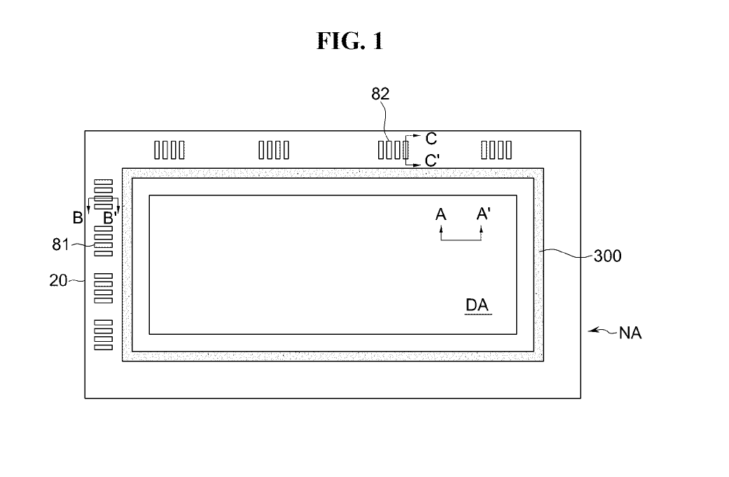

Hereinafter, an uneven pattern formed on a passivation layer of a non-display area will be described in detail with reference to FIGS. 1 to 3.

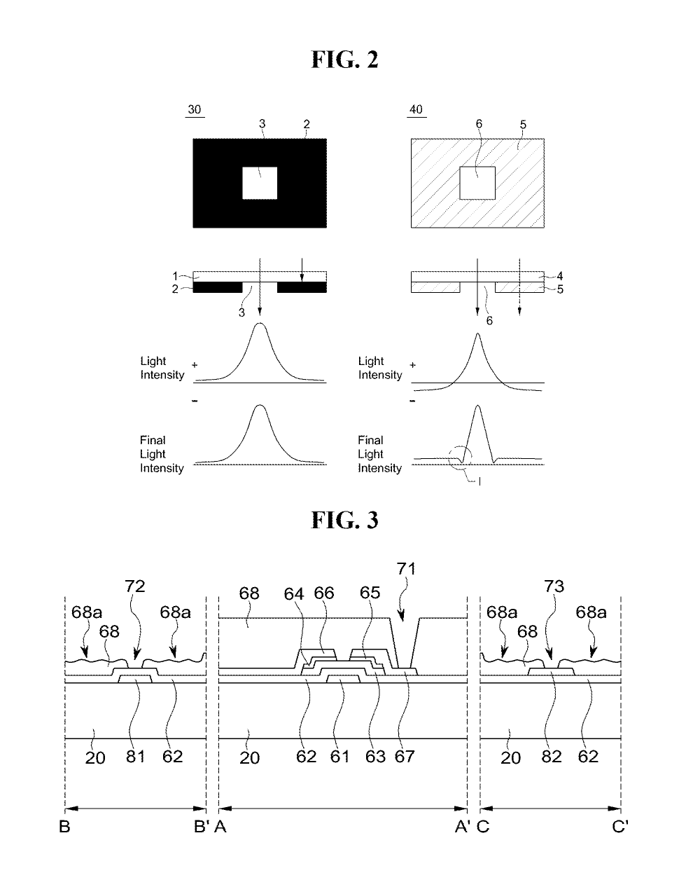

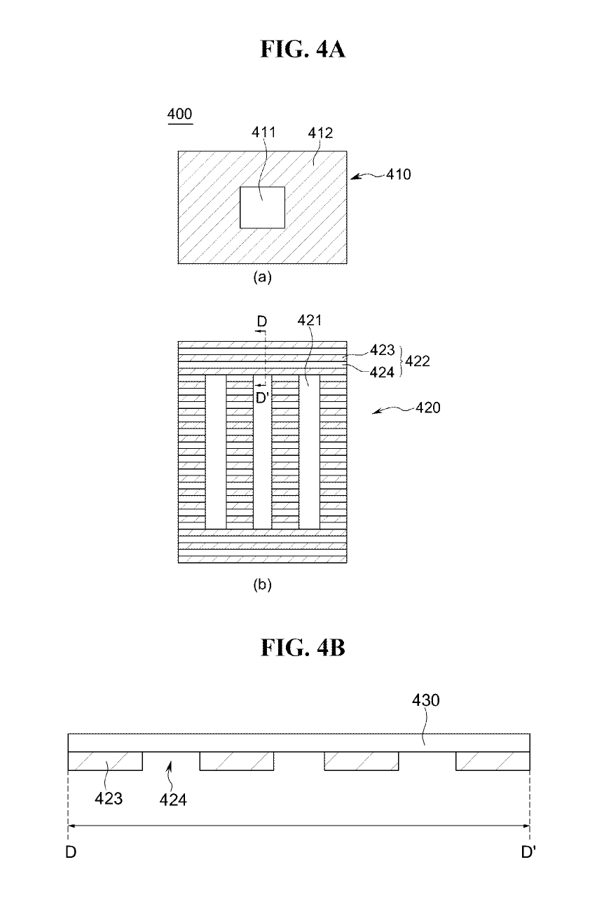

FIG. 1 is a schematic plan view showing a display device according to a first embodiment. FIG. 2 provides comparative cross-sectional views for comparing intensity of light transmitted through different kinds of masks, more specifically, phase shift masks and binary masks. FIG. 3 is cross-sectional views showing an uneven pattern formed on a passivation layer disposed in a non-display area.

Referring to FIG. 1, the display device according to the first embodiment includes a substrate 20 partitioned into two areas: a display area DA and a non-display area NA. A plurality of pixels may be disposed in the display area DA of the substrate 20 and structured so as to display an electronically-defined image. One or more gate pads 81 and data pads 82 may be disposed in the non-display area NA. The gate pads 81 and the data pads 82 need not be all in the non-display area NA. Some or all of the gate pads 81 and data pads 82 may be provided outside the non-display area NA. For instance, as illustrated in FIG. 1, the gate pads 81 and the data pads 82 may be disposed only at an upper side and a left side of the non-display area NA outside a sealing member 300. An area where the gate pads 81 and the data pads 82 are disposed may be called a pad area.

The sealing member 300 may be disposed in the non-display area NA so as to allow the substrate 20 and an opposed light-passing substrate (not shown) to be sealingly bonded to each other so as to form a sealed volume in which the electro-optically active layer (e.g., liquid crystals) may be containerized. The sealing member 300 may include a thermosetting resin such as an epoxy resin.

Referring to FIG. 2, a phase shift mask 40 may be used to form a fine pattern for the following reasons.

A binary mask 30 may have a quartz substrate 1 on which a light blocking layer 2 having an opening 3 is disposed. The phase shift mask 40 may have a quartz substrate 4 on which a phase shift layer 5 having an opening 6 is disposed.

In the binary mask 30, intensity of light passing through the opening 3 is concentrated in an area of the opening 3. However, the binary mask 30 has difficulties in adjusting the light intensity to be suitable for defining high resolution line width boundaries of a fine pattern because the light intensity has a gradual slope of a hypothetical tangent line as depicted in the graphs of FIG. 2.

By contrast, in the phase shift mask 40, light is transmitted through the opening 6 and also through the phase shift layer 5. An exposure dose of light transmitted through the phase shift layer 5 in particular is about 1% to about 10% of the total exposure dose of light irradiated onto the phase shift mask 40.

As illustrated in FIG. 2, destructive interference occurs where the outer boundary of the opening 6 meets with the inner boundary of the phase shift layer 5 so that, due to a phase difference of 180 degrees between the light transmitted through the opening 6 and the light transmitted through the phase shift layer 5, the destructive interference occurs. Light intensity of an area adjacent to the opening 6 and the phase shift layer 5 is lowest in an area marked with circle I in the bottom right graph of FIG. 2 by the destructive interference.

Therefore, the phase shift mask 40 can better concentrate light in a finer pattern area when compared to the binary mask 30. Although the phase shift mask 40 can concentrate light in a small area, the total exposure dose of light transmitted through the phase shift mask 40 is increased such that adjacent material, adjacent to a contact hole is undesirably removed and thus designers must carefully adjust the exposure dose of light supplied by an exposure apparatus so that light to the adjacent areas is not increased too much.

Meanwhile, in the case where contact holes are formed in a passivation layer, the contact holes of the display area are formed concurrently with the contact holes of the pad area. More specifically, one exposure mask is used to form the contact holes of the display area and the pad area, and also to etch the passivation layer of the pad area. For smooth connection between external circuits and pads in the pad area, the passivation layer disposed in the pad area is more etched compared to the passivation layer of the display area so as be lower in terms of height.

As described above, the phase shift mask 40 may be used to form a contact hole of the display area so that the contact hole may fit a fine pattern. In the case where the contact holes that are to be formed in the display area and the non-display area are simultaneously formed utilizing the phase shift mask 40, elements such as conductive lines disposed on a lower portion of the passivation layer of the non-display area may be exposed or otherwise not adequately insulated due to excessive etch back if the total exposure dose of light is increased.

The binary mask 30 including a slit pattern has been conventionally used to etch the passivation layer disposed in the pad area. In the case where a slit pattern line width is simply increased to reduce an exposure dose of transmitted light, intensity contrast (I/C) increases such that an uneven pattern is formed on the passivation layer.

I/C is defined as (Imax−Imin)/(Imax+Imin) where Imax is the maximum intensity of light and Imin is the minimum intensity of light, and it is also a reference value of occurrence of the uneven pattern on the passivation layer. An I/C value relates to resolution originally and as the I/C value decreases, light is evenly distributed over the whole area. When light is incident uniformly on the entire area, the occurrence of the uneven pattern may be reduced. It has been experimentally proved that the uneven pattern is not formed on the passivation layer when the I/C value is about 0.12 or less.

In other words, as illustrated in FIG. 3, the uneven pattern may be formed on the passivation layer 68 disposed in the pad area in the case where the exposure dose of transmitted light is adjusted utilizing the binary mask 30 including the slit pattern. The uneven pattern may have peaks and valleys which alternate with each other. The uneven pattern may have a mosaic or fine slit form and may be formed to have an uneven shape on a surface 68a of the passivation layer 68. In the case where the uneven pattern has a broad amplitude, elements such as conductive lines disposed on a lower portion of the passivation layer 68 may be exposed.

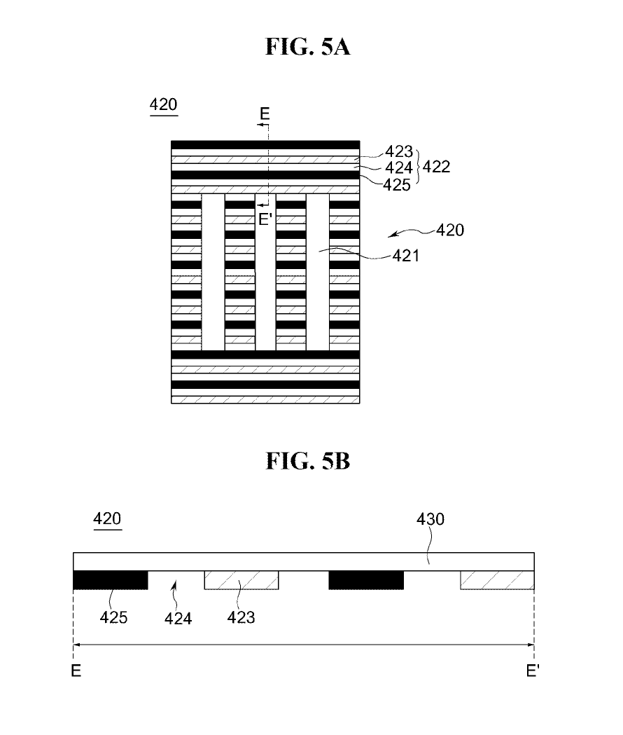

According to the first embodiment, the exposure mask may be used to form a fine contact opening (e.g., hole) in the display area, reduce the uneven pattern on the passivation layer disposed in the pad area, and decrease the exposure dose of light incident upon the pad area. The entire configuration and effect of the exposure mask will be described below with reference to FIGS. 4A to 7D.

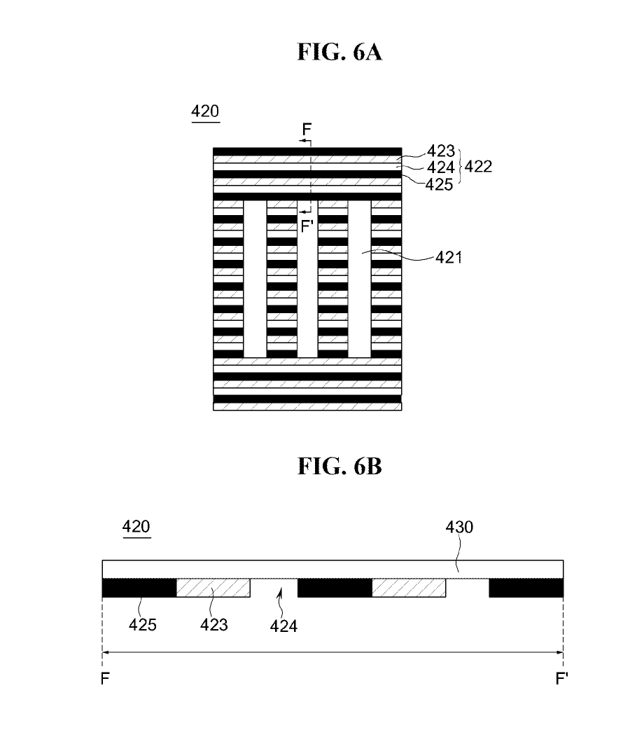

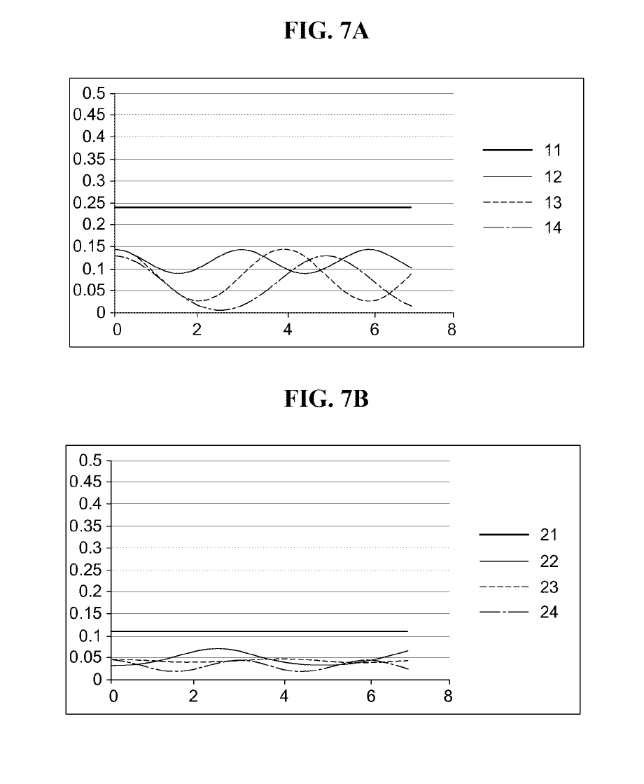

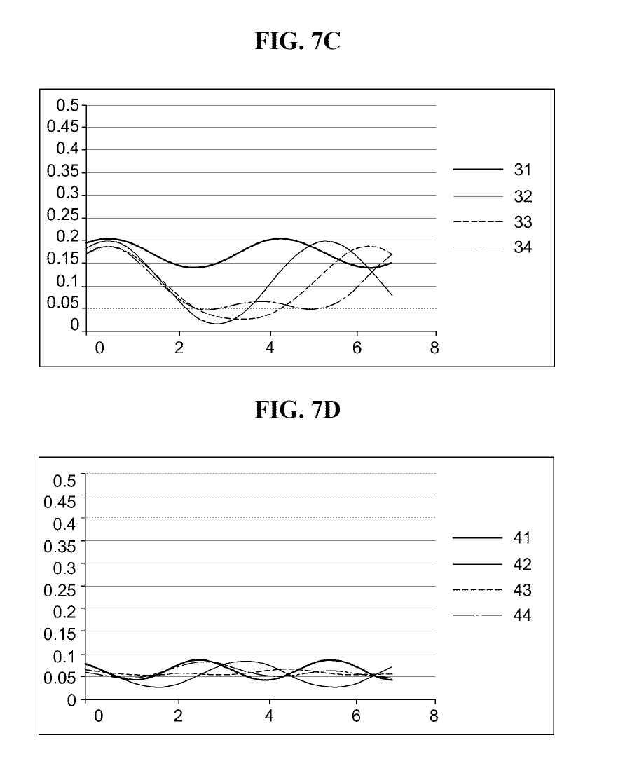

FIGS. 4A and 4B are a plan view and a cross-sectional view, respectively showing a first mask pattern and a second mask pattern according to the first embodiment. FIGS. 5A and 5B are a plan view and a cross-sectional view, respectively showing a second mask pattern according to a second embodiment. FIGS. 6A and 6B are a plan view and a cross-sectional view, respectively showing a second mask pattern according to a third embodiment. FIGS. 7A to 7D are graphs showing the amounts of light incident on a passivation layer of a non-display area according to some embodiments.

Referring to FIGS. 4A and 4B, the exposure mask 400 according to the first embodiment includes a first area and a second area. The first area may include a mask pattern that forms a pattern to be disposed in the display area of the display device. The second area may include a mask pattern that forms a pattern to be disposed in the non-display area of the display device. That is, the first area may include patterns corresponding to the display area of the display device and the second area may include patterns corresponding to the non-display area of the display device. The entire configuration of the exposure mask 400 may vary depending on the display device and for example, the exposure mask 400 may have a quadrilateral shape such that the first area is surrounded by the second area.

The exposure mask 400 may include a first mask pattern 410 and a second mask pattern 420. The first mask pattern 410 and the second mask pattern 420 may be disposed on a mask substrate 430 made of a transparent material such as quartz.

The first mask pattern 410 may be disposed in the first area and may include a first light transmitting unit 411 and a first phase shift unit 412. The first light transmitting unit 411 may be formed to correspond to a size of a contact hole and may be circular or polygonal in shape. The first light transmitting unit 411 may correspond to an opening of the first phase shift unit 412.

The first phase shift unit 412 may surround the first light transmitting unit 411 and may have a light transmittance of about 1% to about 10%. The light transmittance of the first phase shift unit 412 may approach zero (0) in a region adjacent to the first light transmitting unit 411. In other words, the first phase shift unit 412 may change a phase of light so that the phase difference between the light and light passing through the first light transmitting unit 411 is 180 degrees, and thus light transmitted through each region adjacent to the first phase shift unit 412 and the first light transmitting unit 411 may interfere destructively. Therefore, the exposure mask 400 may form a fine contact hole, which may be disposed in the display area, utilizing the first mask pattern 410. Meanwhile, the first phase shift unit 412 may be made of one or more of suitable phase shifting materials such as MoSiN, MoSiON, MoSiCN, MoSiO, or MoSiCON or other by combination of one or more kinds selected from nitrogen (N), oxygen (O), and carbon (C) and based on molybdenum silicide (MoSi).

The second mask pattern 420 may be disposed in the second area and may include a second light transmitting unit 421 and a second phase shift unit 422.

The second light transmitting unit 421 may have a size corresponding to a contact hole to couple an external drive circuit line to a gate pad or a data pad that may be disposed in the non-display area of the display device.

The second phase shift unit 422 may include a plurality of phase shift patterns 423 that are spaced apart and parallel to each other and may also include a light transmission area 424 between the phase shift patterns 423. The second phase shift unit 422 may control an exposure dose in a mask area except for the second light transmitting unit 421.

As illustrated in FIG. 4A, the phase shift patterns 423 may be formed to be spaced apart and parallel to each other and may have a line shape. As illustrated in FIG. 4B, the light transmission area 424 may be an opening between the plurality of phase shift patterns 423.

In the case where light irradiated onto the second mask pattern 420 passes through the second phase shift unit 422, an exposure dose of light passing through the light transmission area 424 may be reduced in a similar way to general phase shift masks. Therefore, an exposure dose of light transmitted through the second phase shift unit 422 may also be reduced, and thus the passivation layer disposed in the non-display area may not be excessively etched and the uneven pattern may have a decreased height difference between the peaks and valleys or the peaks and valleys may have similar height.

The phase shift pattern 423 may have a line width in a range of 0.5 μm to 1.2 μm and the light transmission area 424 may have a line width in a range of 0.8 μm to 1.5 μm.

The phase shift pattern 423 may be made of one or more of suitable phase shifting materials such as MoSiN, MoSiON, MoSiCN, MoSiO, or MoSiCON or other by combination of one or more kinds selected from nitrogen (N), oxygen (O), and carbon (C) and based on molybdenum silicide (MoSi).

Referring now to FIGS. 5A and 5B, the second mask pattern 420 according to the second embodiment further includes a light blocking pattern 425 when compared to the second mask pattern 420 illustrated in FIGS. 4A and 4B. More specifically, the second mask pattern 420 may include a second light transmitting unit 421 and a second phase shift unit 422. The second phase shift unit 422 may include a plurality of phase shift patterns 423 spaced apart and parallel to each other and the light blocking patterns 425 disposed substantially parallel to each other between the phase shift patterns 423, and may also include a light transmission area 424 between the phase shift pattern 423 and the light blocking pattern 425.

The second mask pattern 420 illustrated in FIGS. 5A and 5B may have lower light transmittance overall when compared to the second mask pattern 420 illustrated in FIGS. 4A and 4B. This is because the exposure mask may further include the light blocking pattern 425 configured to block light in the same area.

Meanwhile, the light blocking pattern 425 may include chromium (Cr) and may have a shape of a stripe and be disposed substantially parallel to the phase shift pattern 423.

Referring now to FIGS. 6A and 6B, the second mask pattern 420 according to the third embodiment further includes a light blocking pattern 425 when compared to the second mask pattern 420 illustrated in FIGS. 4A and 4B. Further, the second mask pattern 420 according to the third embodiment includes the light blocking pattern 425 and the phase shift pattern 423 that are adjacent to each other unlike the second mask pattern 420 illustrated in FIGS. 5A and 5B.

In more detail, the second mask pattern 420 may include a second light transmitting unit 421 and a second phase shift unit 422. The second phase shift unit 422 may include a plurality of phase shift patterns 423 spaced apart and parallel to each other and a plurality of light blocking patterns 425 spaced apart and parallel to each other and adjacent to the phase shift patterns 423. The second phase shift unit 422 may also include a light transmission area 424 between at least one pair of the phase shift pattern 423 and the light blocking pattern 425. In other words, although not illustrated, the plurality of phase shift patterns 423 and light blocking patterns 425 may alternately arranged adjacent to each other so that one pattern group may be formed and the light transmission area 424 may be included between the pattern groups.

The second mask pattern 420 illustrated in FIGS. 6A and 6B may have lower light transmittance overall when compared to the second mask pattern 420 illustrated in FIGS. 4A and 4B. This is because the exposure mask may further include the light blocking pattern 425 configured to block light in the same area.

Intensity of light transmitted through the second mask patterns 420 according to the first to third embodiments will be described below with reference to FIGS. 7A to 7D.

FIG. 7A is a graph showing light intensity in the case of using a binary mask including a conventional slit pattern. In the graph, X axis is a horizontal line to show a location of an area of a mask pattern on the passivation layer in the non-display area of the display device, and Y axis is a vertical line to show intensity of transmitted light.

Referring to FIG. 7A, graph curve 11 is the case where the light blocking pattern and the light transmission area have the same line width as each other. In the case of graph curve 11, the light intensity may be uniform such that the uneven pattern may not be formed on the passivation layer, but the maximum intensity of light may be high at a level of 0.24, and thus the passivation layer may be undesirably over-etched. Graph curve 12 is the case where the line width ratio of the light blocking pattern to the light transmission area is 2:1. In the case of graph curve 12, the maximum intensity of light may be low at a level of 0.14, but the intensity of light incident onto the passivation layer may vary depending on the area of a mask pattern so that the uneven pattern may be formed on the passivation layer. Graph curve 13 is the case where the line width ratio of the light blocking pattern to the light transmission area is 3:1. In the case of graph curve 13, the maximum intensity of light may be low at a level of 0.14, but the intensity of light incident onto the passivation layer may vary depending on the area of a mask pattern so that the uneven pattern may be formed on the passivation layer. Graph curve 14 is the case where the line width ratio of the light blocking pattern to the light transmission area is 4:1, and the maximum intensity of light may be lower, but the uneven pattern may also be formed on the passivation layer in a similar way to lines 12 and 13.

FIG. 7B is a graph showing light intensity when light is transmitted through the second mask pattern according to the first embodiment. Referring to FIG. 7B, graph curve 21 is the case where the line width ratio of the phase shift pattern to the light transmission area is 1:1, and the maximum intensity of light is reduced to about 0.112 and the light intensity is uniform regardless of areas of the second mask pattern so that the uneven pattern may not be formed on the passivation layer. Further, graph curve 21 may have a I/C value of zero (0). Graph curve 22 is the case where the line width ratio of the phase shift pattern to the light transmission area is 2:1, and the maximum intensity of light is reduced to about 0.046 and the light intensity differs slightly depending on the area of the second mask pattern. Compared to the graph of FIG. 7A, the height difference between the peaks and valleys of the uneven pattern may somewhat decrease. Graph curve 23 is the case where the line width ratio of the phase shift pattern to the light transmission area is 3:1 and graph curve 24 is the case where the line width ratio of the phase shift pattern to the light transmission area is 4:1. In the case of graph curve 23, the measured I/C value is low at a level of 0.088 and the light intensity is uniform in every area. Graph curve 24 has a value and graph curve similar to graph curve 22. That is, in the case of using the second mask pattern according to the first embodiment, an exposure dose of light irradiated onto the passivation layer may not be too high, and the uneven pattern may not be formed on the passivation layer or may be formed very small. According to the first embodiment, the line width ratio of the phase shift pattern may be adjusted so that the uneven pattern may not be formed and also the exposure dose of light irradiated onto the passivation layer may be reduced. The line width ratio of the phase shift pattern to the light transmission area is for illustrative purposes only, and any line width ratio is available if it decreases the exposure dose of light transmitted through the second mask pattern and allows the light intensity to be uniform in every area of the second mask pattern.

FIG. 7C is a graph showing light intensity when light is transmitted through the second mask pattern according to the second embodiment. Referring to FIG. 7C, graph curve 31 is the case where the line width ratio of the light blocking pattern to the phase shift pattern to the light transmission area is 1:1:1. In the graph curve 31 case, the maximum intensity of light is reduced to about 0.204 and the light intensity differs slightly depending on the area of the second mask pattern such that the uneven pattern may be slightly formed on the passivation layer. Graph curve 32 is the case where the line width ratio of the light blocking pattern to the phase shift pattern to the light transmission area is 1:2:1. Graph curve 33 is the case where the line width ratio of the light blocking pattern to the phase shift pattern to the light transmission area is 1:3:1. Graph curve 34 is the case where the line width ratio of the light blocking pattern to the phase shift pattern to the light transmission area is 1:4:1. In the case of graph curves 32 to 34, the maximum intensity of light is lower than the graph of FIG. 7A and the light intensity varies depending on the area of the second mask pattern such that the uneven pattern may be formed on the passivation layer. According to the second embodiment, the line width ratio of the phase shift pattern may be adjusted so that the uneven pattern may not be formed and also the exposure dose of light irradiated onto the passivation layer may be reduced. Graph curves 31 to 34 are for illustrative purposes only, and any line width ratio is available if it decreases the exposure dose of light transmitted through the second mask pattern and allows the light intensity to be uniform in every area of the second mask pattern.

FIG. 7D is a graph showing intensity of light transmitted through the second mask pattern according to the third embodiment. Referring to FIG. 7D, graph curve 41 is the case where the line width ratio of the light blocking pattern to the phase shift pattern to the light transmission area is 1:1:1. Graph curve 42 is the case where the line width ratio of the light blocking pattern to the phase shift pattern to the light transmission area is 1:2:1. Graph curve 43 is the case where the line width ratio of the light blocking pattern to the phase shift pattern to the light transmission area is 1:3:1. Graph curve 44 is the case where the line width ratio of the light blocking pattern to the phase shift pattern to the light transmission area is 1:4:1. In the case of graph curves 41 to 44, the maximum intensity of light is reduced to near 0.085 and the light intensity differs slightly depending on the area of the second mask pattern but, compared to the graph of FIG. 7A, the height difference between the peaks and the valleys of the uneven pattern may somewhat decrease. That is, in the case of using the second mask pattern according to the third embodiment, the exposure dose of light irradiated onto the passivation layer may not be too high, and the uneven pattern may not be formed on the passivation layer or may be formed very small. According to the third embodiment, the line width ratio of the phase shift pattern may be adjusted so that the uneven pattern may not be formed and also the exposure dose of light irradiated onto the passivation layer may be reduced. The line width ratio of the light blocking pattern to the phase shift pattern to the light transmission area is for illustrative purposes only, and the line width ratio may be available if it decreases the exposure dose of light transmitted through the second mask pattern and allows the light intensity to be uniform in every area of the second mask pattern.

As described above, a line width of the phase shift pattern or the light blocking pattern included in the second mask pattern 420 according to the first to third embodiments may be suitably selected to achieve the desired exposure of the passivation layer in the non-display area, and to suppress occurrence of the uneven pattern on the passivation layer in the non-display area and also excessive etching of the passivation layer.

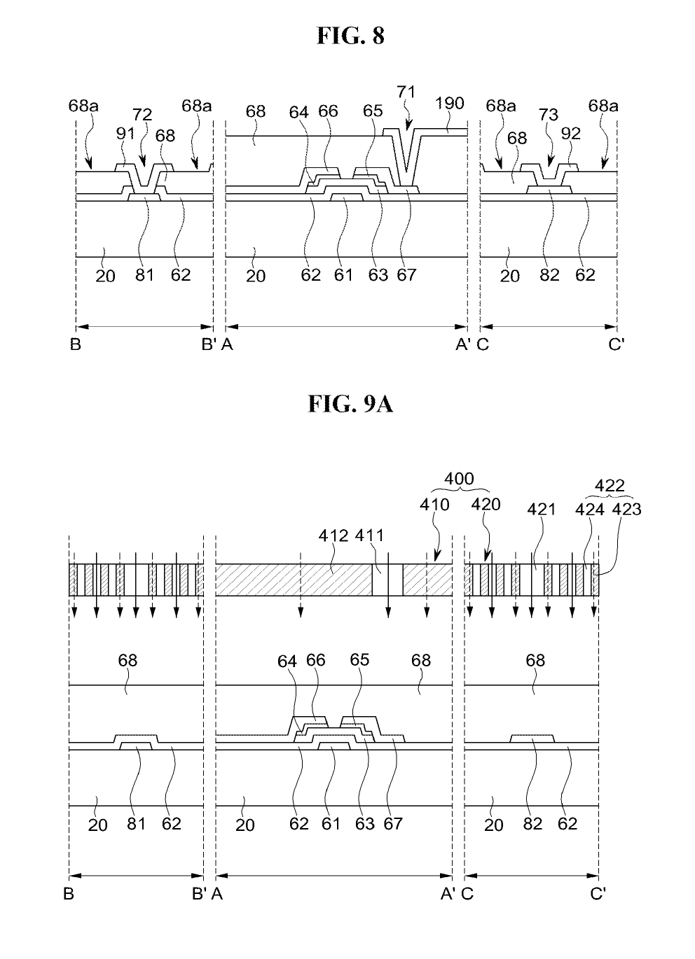

A configuration of a display device will be discussed below with reference to FIG. 8 prior to description of a process of forming contact holes 71, 72, and 73 in the passivation layer 68.

FIG. 8 is cross-sectional views of the display device illustrated in FIG. 1.

Referring to FIG. 8, a gate line (not shown) and a gate electrode 61 may be disposed on a substrate 20 made of glass, plastic, or the like. The gate line may include a plurality of gate electrodes 61 protruding from the gate line and a gate pad 81 corresponding to an end portion having a large area for connection to a different layer or an external drive circuit.

A gate insulating layer 62 made of a silicon nitride (SiNx) or a silicon oxide (SiOx) may be disposed on the gate line (not shown) and the gate electrode 61.

A plurality of semiconductive islands 63 made for example of hydrogenated amorphous silicon (a-Si stands for amorphous silicon), polysilicon, or the like may be disposed on the gate insulating layer 62. The semiconductive islands 63 may mainly extend in a longitudinal direction and may include a plurality of projections (not shown) extending toward the gate electrode 61.

The plurality of semiconductive islands 63 may instead be a semiconductive oxide. The semiconductive oxide may include at least one selected from the group consisting of a zinc (Zn), gallium (Ga), indium (In), and tin (Sn) oxide.

For example, the semiconductive oxide may be made of an oxide based on zinc (Zn), gallium (Ga), tin (Sn), or indium (In), or an oxide semiconductor material, such as zinc oxide (ZnO), indium-gallium-zinc oxide (lnGaZnO₄), Indium-zinc oxide (In—Zn—O), and zinc-tin oxide (Zn—Sn—O), which are complex oxides.

In detail, the semiconductive oxide may include an IGZO-based oxide consisting of indium (In), gallium (Ga), zinc (Zn) and oxygen (O). In addition, the semiconductive oxide may include In—Sn—Zn—O-based metal oxide, In—Al—Zn—O-based metal oxide, Sn—Ga—Zn—O-based metal oxide, Al—Ga—Zn—O-based metal oxide, Sn—Al—Zn—O-based metal oxide, In—Zn—O-based metal oxide, Sn—Zn—O-based metal oxide, Al—Zn—O-based metal oxide, In—O-based metal oxide, Sn—O-based metal oxide, and Zn—O-based metal oxide.

A plurality of ohmic contacts 64 and 65 may be formed on the semiconductive island 63, and are configured to reduce contact resistance. The ohmic contacts 64 and 65 may be made of a material such as n+ hydrogenated amorphous silicon which is doped with n-type impurities such as phosphorus (P) at a high concentration, or may be made of silicide.

A plurality of data lines (not shown) and a plurality of drain electrodes 67 may be formed on the ohmic contacts 64 and 65 and the gate insulating layer 62.

Each data line (not shown) may include a plurality of source electrodes 66 extending toward the gate electrode 61, and a data pad 82 corresponding to an end portion having a wide area for connection to a different layer or an external drive circuit.

The drain electrode 67 may be separated from the data line (not shown), and may face the source electrode 66 with respect to the gate electrode 61.

In detail, the source electrode 66, the drain electrode 67, and the data line (not shown) may be made of a refractory metal such as molybdenum, chromium, tantalum and titanium, or alloys thereof, and may have a multilayer structure that includes a refractory metal layer and low resistance conductive layer. The multilayer structure may include, for example, a double layer consisting of a chromium or molybdenum (an alloy thereof) lower layer and an aluminum (an alloy thereof) upper layer, and a triple layer consisting of a molybdenum (an alloy thereof) lower layer, an aluminum (an alloy thereof) intermediate layer, and a molybdenum (an alloy thereof) upper layer.

One gate electrode 61, one source electrode 66, and one drain electrode 67 may compose one thin film transistor (TFT), together with the projection (not shown) of the semiconductive island 63, and a channel of the TFT may be formed at the projection between the source electrode 66 and drain electrode 67.

A passivation layer 68 may be formed on the gate line (not shown), the data line (not shown), the source electrode 66, the drain electrode 67, and an exposed part of the semiconductive island 63. The passivation layer 68 may be made of an inorganic insulating material such as a silicon nitride (SiNx) or a silicon oxide (SiOx), or of an acrylic organic compound having a small dielectric constant, or of an organic insulating material such as benzocyclobutene (BCB) or perfluorocyclobutane (PFCB), or may be formed to be planarized in a laminated structure including the inorganic and organic insulating materials using a deposition method such as plasma enhanced chemical vapor deposition (PECVD).

The passivation layer 68 may have a plurality of drain contact holes 71 that extend to and expose the respective drain electrodes 67, respectively, a plurality of gate pad contact holes 72 that extend to and expose the respective gate pads 81, respectively, and a plurality of data pad contact holes 73 that extend to and expose the respective data pads 82, respectively.

The passivation layer 68 disposed in the non-display area may be lower in height than that of the display area so that a stepped structure may be formed. Due to such a step, compression force may be sufficiently applied to anisotropic conductive film (ACF) in an outer lead bonding process for a pad unit, thereby enhancing adhesive strength with the pads 81 and 82.

In the case where the second mask pattern 420 according to the first to third embodiments is used for exposure, the uneven pattern may not be formed on an upper surface 68a of the passivation layer in the non-display area or may be very small.

Therefore, the passivation layer 68 may ensure connection between an external drive circuit and the pads 81 and 82 in the non-display area and may not expose lines such as internal circuits to the outside.

A plurality of pixel electrodes 190 may be formed on the passivation layer 68. The pixel electrode 190 may be made of a transparent conductive material such as ITO or IZO, or a reflective metal such as aluminum, silver, or alloys thereof.

The pixel electrode 190 may be physically and electrically connected to the drain electrode 67 through the contact holes 71 and 72, and may receive data voltage from the drain electrode 67. An electric field may be generated by the pixel electrode 190, to which the data voltage is applied, and a common electrode (not shown) of a different display substrate (not shown) to which common voltage is applied, thereby determining an orientation of liquid crystal molecules of a liquid crystal layer (not shown) between the two electrodes. The pixel electrode 190 and the common electrode may define a capacitor (hereinafter referred to as a “liquid crystal capacitor”) to maintain the applied voltage after a thin film transistor is turned off.

Meanwhile, an auxiliary gate pad 91 and an auxiliary data pad 92 may be formed on the gate pad 81 and the data pad 82 to which the auxiliary gate pad 91 and the auxiliary data pad 92 may be coupled through the contact holes 72 and 73. The auxiliary gate pad 91 and the auxiliary data pad 92 may be configured to aids in adhesion between the pads 81 and 82 and external circuits and to protect the pads 81 and 82. The auxiliary gate pad 91 and the auxiliary data pad 92 may not be essential components and may be selected where necessary.

Meanwhile, in the case where embodiments are used and relate instead to an organic light emitting diode (OLED) display, the OLED display may include an organic light emitting layer (not shown) on the pixel electrode 190 and an opposite electrode (not shown) disposed on the organic light emitting layer.

The pixel electrode 190 may be disposed to correspond to an opening of a pixel defining layer (not shown), but it is not necessarily disposed in the opening of the pixel defining layer. The pixel electrode 190 may be disposed under the pixel defining layer so that a portion of the pixel electrode 190 may overlap the pixel defining layer. The pixel defining layer may be made of a polyacrylate resin, polyimide resin, silica-based inorganic material, or the like.

The organic light emitting layer (not shown) may be formed on the pixel electrode 190, and the opposite electrode (not shown) serving as a cathode may be formed on the organic light emitting layer. As described above, the OLED display may be formed by including the pixel electrode 190, the organic light emitting layer, and the opposite electrode.

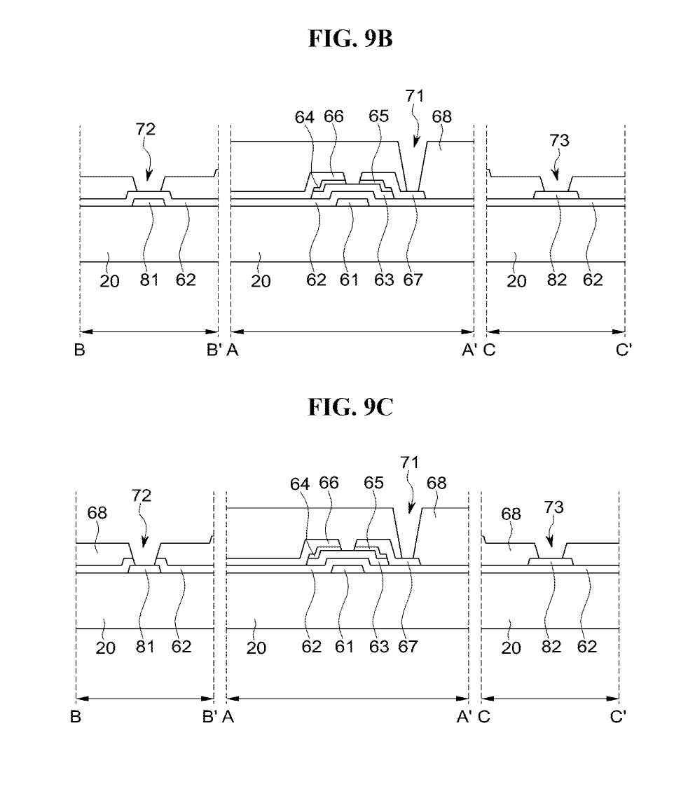

Hereinafter, a method of forming the drain contact hole of the display area and the pad contact hole of the non-display area using the exposure mask according to the first embodiment will be described with reference to FIGS. 9A to 9C.

FIGS. 9A to 9C are cross-sectional views showing a method of forming a contact hole of a display device using the exposure mask according to the first embodiment.

As illustrated in FIG. 9A, the passivation layer 68 made of an organic insulating layer may be applied first. In this embodiment, the passivation layer 68 in positive photoresist (Posi PR) may be formed, but the passivation layer 68 may also be applied with a non-photosensitive material. The passivation layer 68 may be formed to be laminated with insulating layers such as a silicon nitride (SiNx) layer or a silicon oxide (SiOx) layer. Alternatively, the passivation layer 68 may be formed to be planarized in a laminated structure including the inorganic and organic insulating materials. When the organic layer is a positive photoresist (Posi PR) layer, a pattern may remain in a region that does not receive light, whereas the pattern may be removed over a certain part thereof from a region that receives light.

The exposure mask 400 may be disposed on an upper portion of the passivation layer 68 so as to adjust the amount of light transmission. The exposure mask 400 may include the first mask pattern 410 and the second mask pattern 420.

The first light transmitting unit 411 of the first mask pattern 410 may be disposed on a region where the drain contact hole is to be formed, and the first phase shift unit 412 may be disposed on the passivation layer 68 around the region where the drain contact hole is to be formed. The second light transmitting unit 421 of the second mask pattern 420 may be disposed on a region where a contact hole to expose the gate pad 81 and the data pad 82 is to be formed, and the second phase shift unit 422 may be disposed on the passivation layer 68 in the non-display area.

Therefore, light irradiated to the first light transmitting unit 411 may be almost all transmitted therethrough and may reach the region where the drain contact hole is to be formed.

Further, light irradiated to the second light transmitting unit 421 may be almost all transmitted therethrough and may reach the region where the contact hole to expose the gate pad 81 and the data pad 82 is to be formed. Light of which the expose dose is less than 10% of the total exposure dose of light irradiated to the second phase shift unit 422 may be irradiated to the passivation layer 68 in the non-display area.

As illustrated in FIG. 9B, the exposed passivation layer 68 may be developed to form the contact holes 71, 72, and 73 that extent to and expose the drain electrode 67 and the pads 81 and 82. Further, the passivation layer 68 in the non-display area may be partially etched to be lower in height than that of the display area.

As illustrated in FIG. 9C, the gate insulating layer 62 may be etched such that the gate pad contact hole 72 may be formed to expose the gate pad 81.

From the foregoing, it will be appreciated that various embodiments in accordance with the present disclosure have been described herein for purposes of illustration, and that various modifications may be made without departing from the scope and spirit of the present teachings. Accordingly, the various embodiments disclosed herein are not intended to be limiting of the true scope and spirit of the present teachings.

What is claimed is:

1. A display device comprising:
a substrate comprising a display area and a non-display area;
a gate line and a data line disposed on the substrate;
a thin film transistor disposed on the display area, the thin film transistor being coupled to the gate line and the data line;
a pad disposed in the non-display area;
a passivation layer disposed on the thin film transistor and the pad; and
a pixel electrode coupled to the thin film transistor,
wherein the passivation layer has a thickness that is smaller in the non-display area than in the display area, and the passivation layer has a thickness of about 0.1 μm to about 1 μm in the non-display area.

2. The display device of claim 1, wherein the passivation layer has an opening that extends to a drain electrode of the thin film transistor and the pad.

3. An exposure mask comprising:
a mask substrate comprising a first area and a second area;
a first mask pattern disposed in the first area, the first mask pattern having a first light transmitting unit; and
a second mask pattern disposed in the second area, the second mask pattern having a second light transmitting unit and a second phase shift unit.

4. The exposure mask of claim 3, wherein the first mask pattern comprises a first phase shift unit surrounding the first light transmitting unit.

5. The exposure mask of claim 4, wherein the first light transmitting unit has a circular or polygonal shape.

6. The exposure mask of claim 4, wherein the first phase shift unit has a light transmittance of about 1% to about 10%.

7. The exposure mask of claim 3, wherein the second phase shift unit comprises a plurality of phase shift patterns spaced apart and parallel to each other, and a light transmission area between the phase shift patterns.

8. The exposure mask of claim 7, wherein the phase shift pattern has a linewidth of about 0.5 μm to about 1.2 μm, and the light transmission area has a linewidth of about 0.8 μm to about 1.5 μm.

9. The exposure mask of claim 8, wherein the phase shift pattern and the light transmission area have a shape of a stripe.

10. The exposure mask of claim 3, wherein the second phase shift unit comprises:
a plurality of phase shift patterns spaced apart and parallel to each other;
light blocking patterns placed substantially parallel to each other between the phase shift patterns; and
a light transmission area between the phase shift pattern and the light blocking pattern.

11. The exposure mask of claim 10, wherein the phase shift pattern, the light blocking pattern, and the light transmission area have a shape of a stripe.

12. The exposure mask of claim 3, wherein the second phase shift unit comprises:
at least one phase shift pattern spaced apart and parallel to each other;
at least one light blocking pattern adjacent to the phase shift pattern; and
a light transmission area between the phase shift pattern and the light blocking pattern that are adjacent to each other.

13. The exposure mask of claim 12, wherein the phase shift pattern, the light blocking pattern, and the light transmission area have a shape of a stripe.

14. A method for manufacturing a display device, the method comprising:
applying a passivation layer-forming material on a substrate comprising a display area and a non-display area;
exposing the passivation layer-forming material applied to the display area and the non-display area to light using different patterns on an exposure mask;
forming a contact hole by developing the light-exposed passivation layer-forming material; and
forming a passivation layer by applying heat treatment to the residual passivation layer-forming material.

15. The method of claim 14, wherein the exposure mask comprises:
a mask substrate comprising a first area and a second area;
a first mask pattern disposed in the first area, the first mask pattern having a first light transmitting unit; and
a second mask pattern disposed in the second area, the second mask pattern having a second light transmitting unit and a second phase shift unit.

16. The method of claim 15, wherein the first mask pattern comprises a first phase shift unit surrounding the first light transmitting unit.

17. The method of claim 15, wherein the second phase shift unit comprises a plurality of phase shift patterns spaced apart and parallel to each other, and a light transmission area between the phase shift patterns.

18. The method of claim 15, wherein the second phase shift unit comprises:
a plurality of phase shift patterns spaced apart and parallel to each other;
light blocking patterns placed substantially parallel to each other between the phase shift patterns; and
a light transmission area between the phase shift pattern and the light blocking pattern.

19. The method of claim 15, wherein the second phase shift unit comprises:
at least one phase shift pattern spaced apart and parallel to each other;
at least one light blocking pattern adjacent to the phase shift pattern; and
a light transmission area between the phase shift pattern and the light blocking pattern that are adjacent to each other.
